(19) United States
(12) Patent Application Publication
(10) Pub. No.: US 2026/0239629 A1
(43) Pub. Date: Aug. 13, 2026

(54) SEMICONDUCTOR DEVICE AND METHODS OF FORMING THE SAME

(71) Applicant: NANYA TECHNOLOGY CORPORATION, New Taipei City (TW)

(72) Inventor: Hsu CHIANG, New Taipei City (TW)

(21) Appl. No.: 19/047,645

(22) Filed: Feb. 7, 2025

(51) Int. Cl. H01L 23/00; H01L 21/768; H01L 23/48; H01L 25/16; H10B 12/00; H10B 80/00

(52) U.S. Cl. CPC H10B 80/00; H10W 20/023; H10W 20/20; H10W 90/00; H10B 12/00; H10W 72/944; H10W 80/312; H10W 80/327; H10W 80/743; H10W 90/792

(57) ABSTRACT

A method of forming a semiconductor device, comprising forming a logic structure, forming dynamic random access memory (DRAM) structures, vertically stacking the DRAM structures into at least one DRAM stack, disposing the at least one DRAM stack on the backside of the first substrate of the logic structure, and filling a molding layer around the DRAM stack. The semiconductor device is also disclosed.

### BACKGROUND

### Field of Invention

The present disclosure relates to semiconductor device and methods of forming the same. More particularly, the present disclosure relates to high bandwidth memory with hybrid bond.

### Description of Related Art

For conventional 3D stacked chip packages, such as high bandwidth memory (HBM), use bumps for chip connection and underfills for mechanical strength improvement. However, bumps and underfills will limit speed and generate heat during the chip operation. Further, stacked chip packages make yield decreased, and the thickness of the stacked chip packages limit the usage in some applications. Thus, the improvement of the thickness and the heat dissipation is crucial for 3D stacked chip packages.

### SUMMARY

The present disclosure provides a method of forming a semiconductor device, comprising forming a logic structure. The logic structure includes a first substrate including a frontside and a backside opposite to the frontside, a first through silicon via (TSV) formed in the first substrate and penetrating through the frontside and the backside of the first substrate, a frontside redistribution layer (RDL) disposed on the frontside of the first substrate and connected to the first TSV, a bump disposed on the RDL and coupled to the first TSV through the frontside RDL, a backside RDL disposed on the backside of the first substrate and connected to the first TSV, a backside dielectric layer formed on the backside redistribution layer, a backside metal pad disposed in the backside dielectric layer and coupled to the first TSV through the backside RDL, wherein a backside surface of the backside metal pad of the logic structure is coplanar with a backside surface of the backside dielectric layer of the logic structure. The method further comprises forming dynamic random access memory (DRAM) structures. Each of the plurality of DRAM structures includes a second substrate including a frontside and a backside opposite to the frontside, a second TSV penetrating through the frontside and the backside of the second substrate, a RDL disposed on the frontside of the second substrate and connected to the second TSV, a frontside dielectric layer disposed on the RDL, a metal pad disposed in the frontside dielectric layer and coupled to the second TSV through the RDL, a backside dielectric layer disposed on the backside of the second substrate, wherein a backside surface of the second TSV is coplanar with a backside surface of the backside dielectric layer of the DRAM structure. The method further comprises vertically stacking the DRAM structures into at least one DRAM stacking, disposing the at least one DRAM stacking on the backside of the first substrate of the logic structure, wherein the second TSV of most bottom DRAM structure of the DRAM stacking contacts the backside metal pad of the logic structure, and the backside dielectric layer of the most bottom the DRAM structure of the DRAM stack contacts the backside dielectric layer of the logic structure. The method further comprises filling a molding layer around the DRAM stack.

The present disclosure provides a semiconductor device, comprising a logic structure, a DRAM stack and a molding layer. The logic structure includes a first substrate, a first through silicon via (TSV), a frontside redistribution layer (RDL), a protecting layer, a frontside metal pad, a bump, a backside RDL, a backside dielectric layer, a backside metal pad. The first substrate includes a frontside and a backside opposite to the frontside. The first TSV is in the first substrate and penetrating through the frontside and the backside of the first substrate. The frontside RDL is on the frontside of the first substrate and connected to the first TSV. The protecting layer is on the frontside RDL. The frontside metal pad is on the frontside RDL through the protecting layer. The bump is on the frontside metal pad. The backside RDL is on the backside of the first substrate and connected to the first TSV. The backside dielectric layer is on the backside redistribution layer. The backside metal pad is in the backside dielectric layer and coupled to the first TSV through the backside RDL. The DRAM stack is formed of one or more DRAM structure vertically stacked. Each of the one or more DRAM structure comprises a second substrate, a second TSV, a DRAM cell, a RDL, a frontside dielectric layer, a metal pad and a backside dielectric layer. The second substrate includes a frontside and a backside opposite to the frontside. The second TSV penetrates through the frontside and the backside of the second substrate. The DRAM cell is on the frontside of the second substrate. The RDL is on the frontside of the second substrate around the DRAM cell and connected to the second TSV. The frontside dielectric layer is on the RDL. The metal pad is in the frontside dielectric layer and coupled to the second TSV through the RDL. The backside dielectric layer is on the backside of the second substrate. The DRAM stacking disposed on the backside of the first substrate of the logic structure, the second TSV of most bottom DRAM structure of the DRAM stacking contacts the backside metal pad of the logic structure, and the backside dielectric layer of the most bottom the DRAM structure of the DRAM stacking contacts the backside dielectric layer of the logic structure. The molding layer is on the logic structure surrounding the DRAM stack.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-11 are cross-sectional views of various formation stages of a method of forming a semiconductor device according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

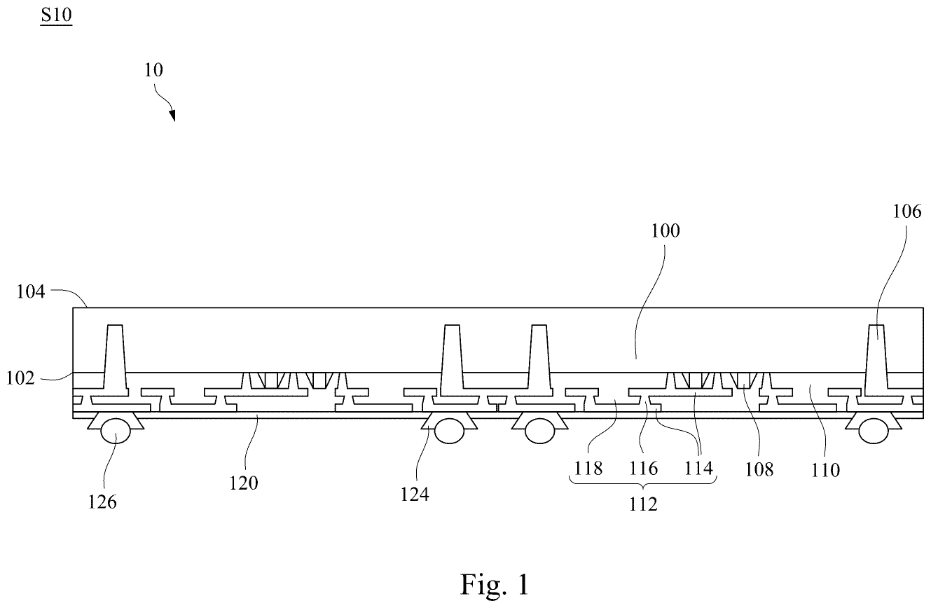

FIGS. 1-11 are cross-sectional views of various formation stages of a method of forming a semiconductor device 30 according to some embodiments of the present disclosure.

Referring to FIG. 1, the method begins from step S10. A logic chip 10 is provided. The logic chip 10 includes a substrate 100 and through silicon vias (TSV) 106 formed in the substrate 100. The substrate 100 includes a frontside 102 and a backside 104 opposite to the frontside 102. A material of the substrate 100 may include silicon (Si). The TSVs 106 extend upwardly in a direction of the frontside 102 of the substrate 100. A material of the TSVs 106 may be conductive material, such as copper (Cu). Transistors 108 are disposed on the frontside 102 of the substrate 100. A first frontside dielectric layer 110 is formed on the frontside 102 of the substrate 100 and overlying the transistors 108. In some embodiments, a frontside surface of the first frontside dielectric layer 110 is coplanar with frontside surfaces of the TSVs 106. A frontside redistribution layer 112 is formed on the first frontside dielectric layer 110 and the TSVs 106. The frontside redistribution layer 112 includes frontside traces 114, frontside vias 116 and a second frontside dielectric layer 118. The frontside traces 114 are disposed in a different height level in a direction parallel to the substrate 100, and the frontside vias 116 are disposed between the adjacent frontside traces 114 at different height level and connected to the frontside traces 114, which are in a direction perpendicular to the substrate 100. Most bottom frontside traces 114 further contact the frontside portions of the TSVs 106. Both of the frontside traces 114 and the frontside vias 116 are arranged in the second frontside dielectric layer 118. In some embodiments, the frontside traces 114 and the frontside via 116 are made of conductive material, such as copper (Cu). A protecting layer 120 is disposed on the frontside redistribution layer 112, overlying frontside surfaces of the frontside traces 114 and the second frontside dielectric layer 118. In some embodiments, the protecting layer 120 may include silicon nitride. Frontside metal pads 124 are formed through the protecting layer 120 and connected to the frontside traces 114. Bumps 126 are disposed on the frontside metal pads 124. The bumps 126 are coupled to the frontside redistribution layer 112 through the frontside metal pads 124.

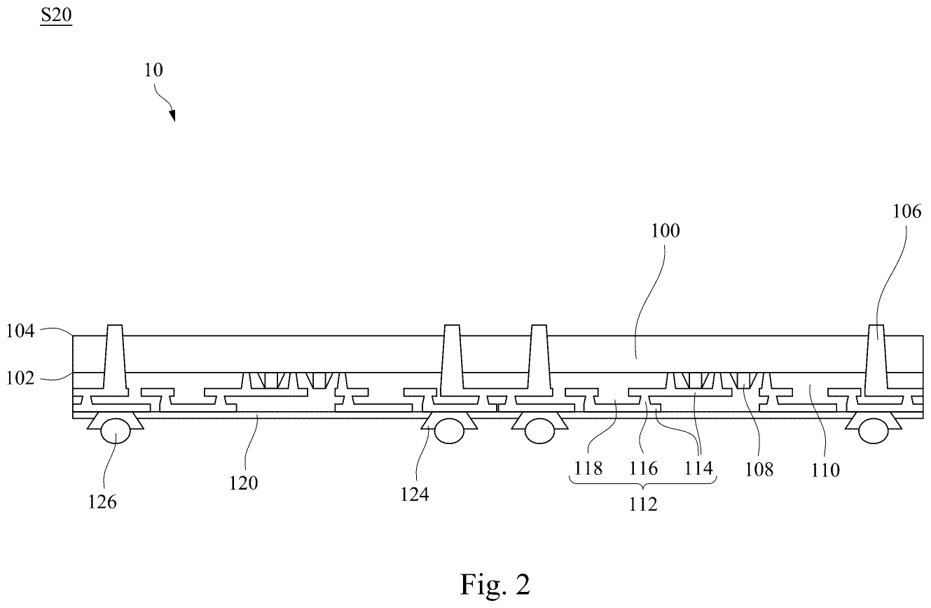

Referring to FIG. 2, the method goes to step S20. A portion of the backside 104 of the substrate 100 is removed to form a thinned substrate 100. In some embodiments, the removal of the portion of the backside 104 of the substrate 100 is performed by the removal operation, such as planarizing process, grinding process or etching process. After the removal of the portion of the backside 104 of the substrate 100, the TSVs 106 penetrate the frontside 102 and the backside 104 of the thinned substrate 100, and backside portions of the TSVs 106 are revealed. In other words, the backside portions of the TSVs 106 are protruding from the backside 104 of the thinned substrate 100.

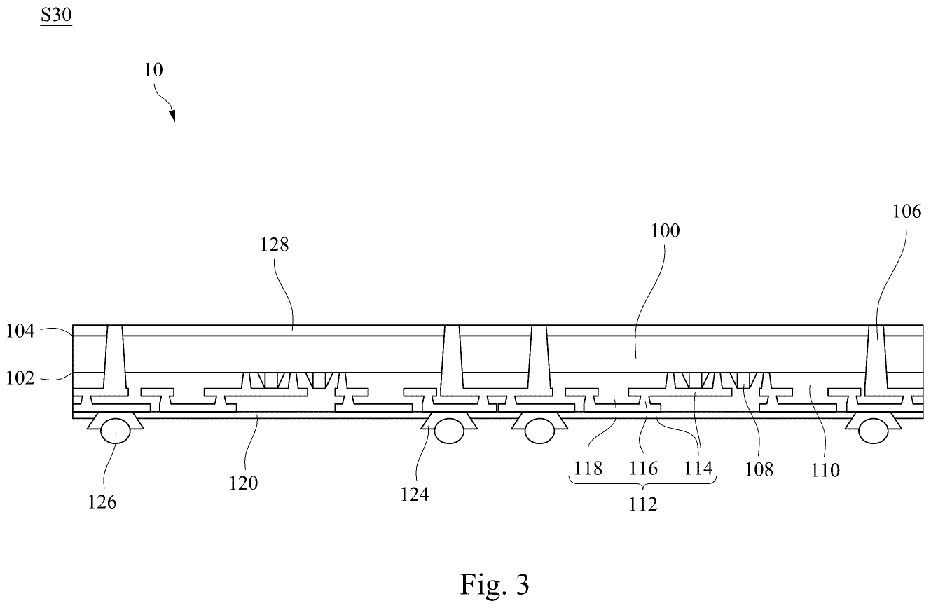

Referring to FIG. 3, the method goes to step S30. A first backside dielectric layer 128 is formed on the backside 104 of the thinned substrate 100. The formation of the first backside dielectric layer 128 uses deposition tool to deposit a dielectric material overlying the backside 104 of the thinned substrate 100 and the backside portions of the TSVs 106, then removes a portion of the dielectric material over backside surfaces of the TSVs 106 to expose the backside surfaces of the TSVs 106. In some embodiments, the backside surfaces of the TSVs 106 are coplanar with a backside surface of the first backside dielectric layer 128. In some embodiments, the dielectric material may include any suitable material, such as silicon oxide and silicon nitride. In some embodiments, the portion of the dielectric material may be removed by any suitable removal operation, such as planarizing process and etching process.

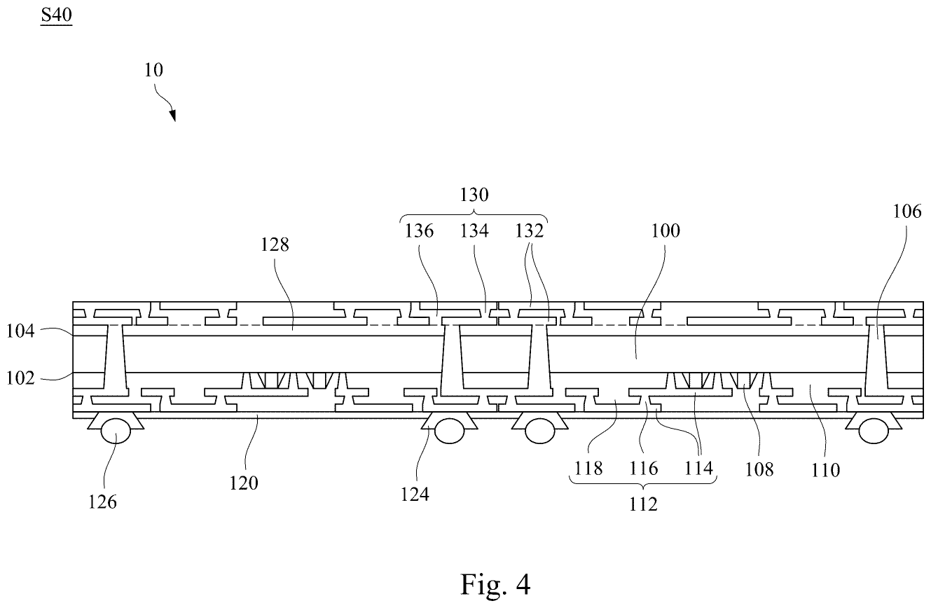

Referring to FIG. 4, the method goes to step S40. A backside redistribution layer 130 is formed on the first backside dielectric layer 128 and the backside portions of the TSVs 106. The backside redistribution layer 130 includes backside traces 132, backside vias 134 and a second backside dielectric layer 136. The backside traces 132 are disposed in a different height level in a direction parallel to the substrate 100, and the backside vias 134 are disposed between the adjacent backside traces 132 at different height level and connected to the backside traces 132, which are in a direction perpendicular to the substrate 100. Most bottom backside traces 132 are further coupled to the backside portions of the TSVs 106. Both of the backside traces 132 and the backside vias 134 are arranged in the second backside dielectric layer 136, and backside surfaces of the backside traces 132 are coplanar with a backside surface of the second backside dielectric layer 136. In some embodiments, the backside traces 132 and the backside vias 134 are made of conductive material, such as copper (Cu).

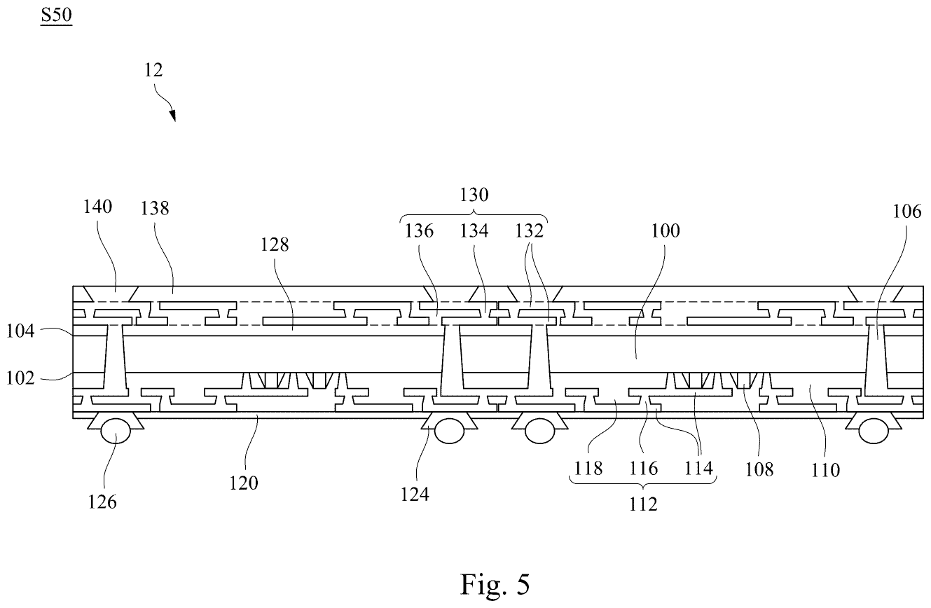

Referring to FIG. 5, the method goes to step S50. A logic structure 12 is formed. A third backside dielectric layer 138 and backside metal pads 140 in the third backside dielectric layer 138 are formed on the backside redistribution layer 130 to form the logic structure 12. The backside metal pads 140 contact the backside traces 132 of the backside redistribution layer 130, and are coupled to the TSVs 106 through the backside redistribution layer 130. In some embodiments, a backside surface of the third backside dielectric layer 138 is coplanar with backside surfaces of the backside metal pads 140.

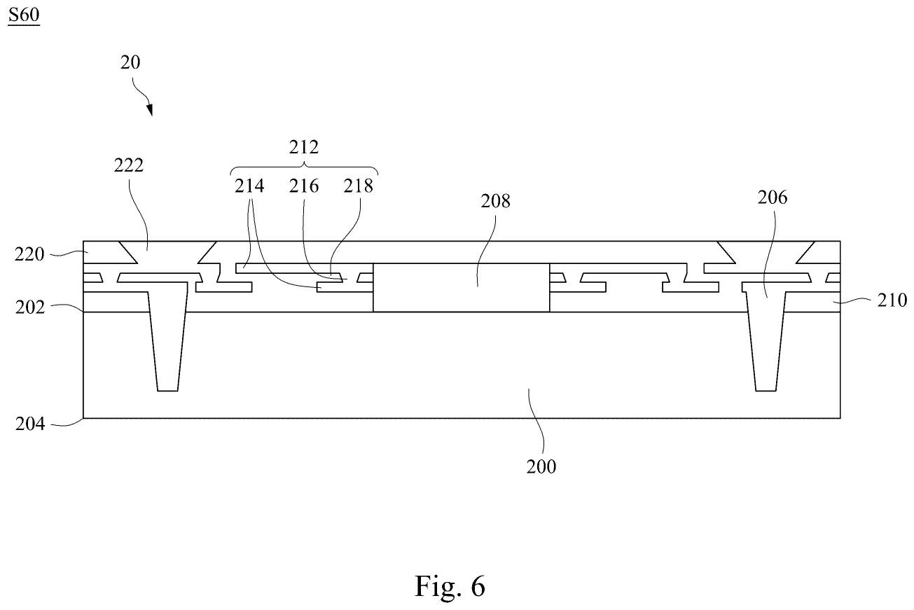

Referring to FIG. 6, the method goes to step S60. A dynamic random access memory (DRAM) chip 20 is provided. The DRAM chip 20 includes a substrate 200 and TSVs 206 formed in the substrate 200. The substrate 200 includes a frontside 202 and a backside 204 opposite to the frontside 202. A material of the substrate 200 may include silicon (Si). The TSVs 206 extend upwardly in a direction of the frontside 202 of the substrate 200. A material of the TSVs 206 may be conductive material, such as copper (Cu). A first frontside dielectric layer 210 is formed on the frontside 202 of the substrate 200 surrounding frontside portions of the TSVs 206. In some embodiments, a frontside surface of the first frontside dielectric layer 210 is coplanar with frontside surfaces of the TSVs 206. A redistribution layer 212 is formed on the first frontside dielectric layer 210 and the TSVs 206. The redistribution layer 212 includes traces 214, vias 216 and a second frontside dielectric layer 218. The traces 214 are disposed in a different height level in a direction parallel to the substrate 200, and the vias 216 are disposed between the adjacent traces 214 at different height level and connected to the traces 214, which are in a direction perpendicular to the substrate 200. The traces 214 are further coupled to the frontside portions of the TSVs 206. Both of the traces 214 and the vias 216 are arranged in the second frontside dielectric layer 218. In some embodiments, the traces 214 and the vias 216 are made of conductive material, such as copper (Cu). A third frontside dielectric layer 220 and metal pads 222 in the third frontside dielectric layer 220 are on the redistribution layer 212. The metal pads 222 are connected to the traces 214, and are coupled to the TSVs 206 through the redistribution layer 212. In some embodiments, frontside surfaces of the metal pads 222 are coplanar with a frontside surface of the third frontside dielectric layer 220. The first frontside dielectric layer 210, the second frontside dielectric layer 218 and the third frontside dielectric layer 220 are collectively referred to a frontside dielectric layer. The DRAM chip 20 further includes a DRAM cell 208 disposed in the frontside dielectric layer and connected to the traces 214.

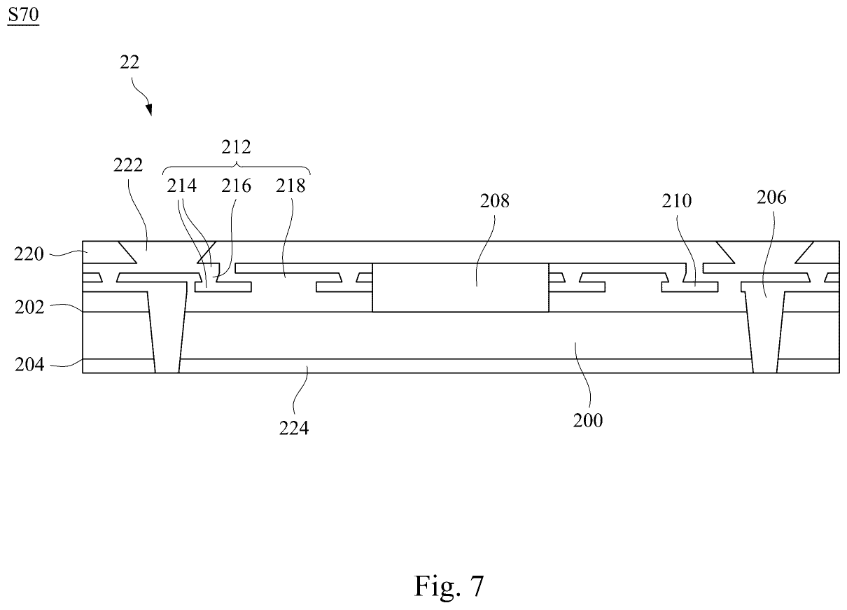

Referring to FIG. 7, the method goes to step S70. A DRAM structure 22 is formed. A portion of the backside 204 of the substrate 200 is removed to form a thinned substrate 200. In some embodiments, the removal of the portion of the backside 204 of the substrate 200 is performed by the removal operation, such as planarizing process, grinding process or etching process. After the removal of the portion of the backside 204 of the substrate 200, the TSVs 206 penetrate the frontside 202 and the backside 204 of the thinned substrate 200, and backside portions of the TSVs 206 are revealed. In other words, the backside portions of the TSVs 206 are protruding from the backside 204 of the thinned substrate 200. A backside dielectric layer 224 is formed on the backside 204 of the thinned substrate 200 surrounding the backside portions of the TSVs 206. The backside dielectric layer 224 may be formed by depositing a dielectric material on the backside 204 of the thinned substrate 200 and overlying the backside portions of the TSVs 206, then removes a portion of the dielectric material on backside surfaces of the TSVs 206. In some embodiments, a backside surface of the backside dielectric layer 224 is coplanar with the backside surfaces of the TSVs 206.

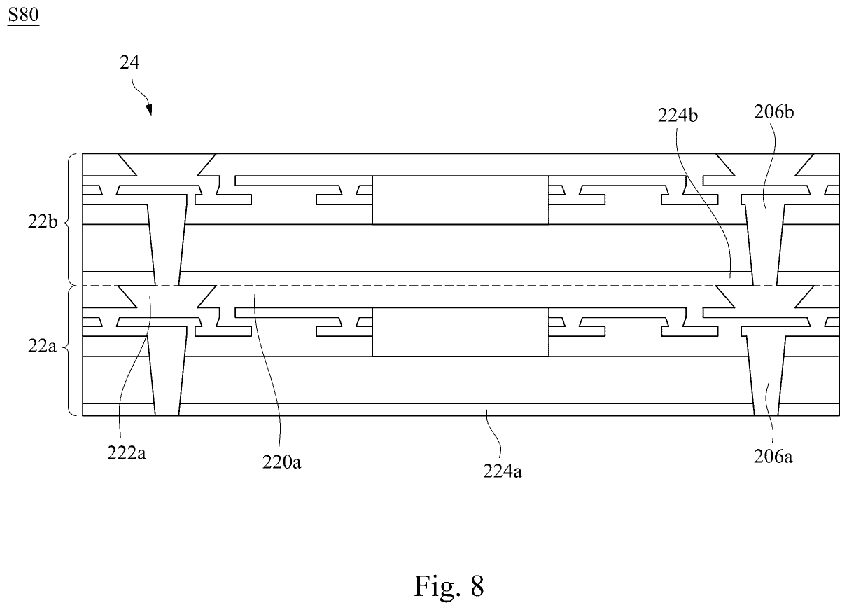

Referring to FIG. 8, the method goes to step S80. A DRAM stacking 24 is formed. A second DRAM structure 22b is stacked vertically on a first DRAM structure 22a to form the DRAM stacking 24. The second DRAM structure 22b bonds to the first DRAM structure 22a by hybrid bond to form the DRAM stacking 24. A backside of the second DRAM structure 22b faces a frontside of the first DRAM structure 22a. The second DRAM structure 22b bonds to the third frontside dielectric layer 220a and the metal pads 222a in the third frontside dielectric layer 220a of the first DRAM structure 22a. For example, the third frontside dielectric layer 220a of the first DRAM structure 22a can bond directly to the backside dielectric layer 224b of the second DRAM structure 22b, and the metal pads 222a of the first DRAM structure 22a can be bonded directly to the TSVs 206b of the second DRAM structure 22b. In some embodiments, a bonding between the third frontside dielectric layer 220a and the backside dielectric layer 224b may be referred as a dielectric to dielectric bond, and a bonding between the metal pads 222a and the TSVs 206b may be referred as a metal to metal bond. The hybrid bond process further couple the first DRAM structure 22a to the second DRAM structure 22b through the metal to metal bond. Thus, the first DRAM structure 22a is electrically connected to the second DRAM structure 22b by physically connecting to each other. After the formation of the DRAM stacking 24, TSVs 206a and a backside dielectric layer 224a of the first DRAM structure 22a are exposed. DRAM stacking 24 are formed of two DRAM structures 22 stacked vertically, but the present disclosure is not limited thereto. In some embodiments, DRAM stacking 24 may be formed of a plurality of the DRAM structures 22. In some embodiments, the DRAM stacking 24 may be formed by vertically and aligned stacking a DRAM wafer on another DRAM wafer to form a stacked DRAM wafer, then dicing the stacked DRAM wafer into a plurality of the DRAM stackings 24.

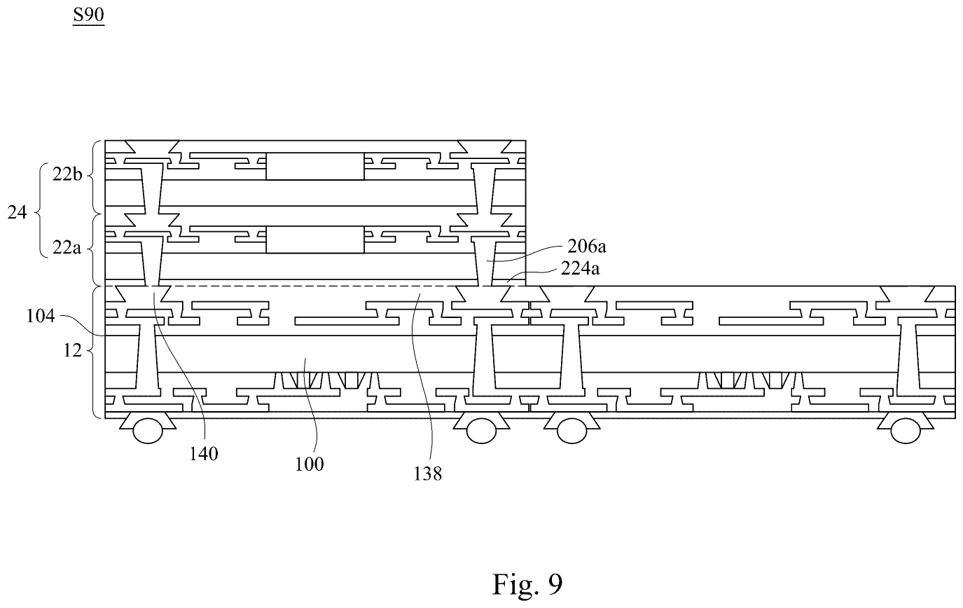

Referring to FIG. 9, the method goes to step S90. The DRAM stacking 24 is stacked on the backside 104 of the thinned substrate 100 of the logic structure 12. The TSVs 206a of the first DRAM structure 22a of the DRAM stacking 24 bond to the backside metal pads 140 of the logic structure 12 to form the metal to metal bond between the logic structure 12 and the DRAM stacking 24. In some embodiments, the TSVs 206a of the first DRAM structure 22a of the DRAM stacking 24 directly contact the backside metal pads 140 of the logic structure 12. The metal to metal bond may be formed through an anneal process, such as Cu anneal. The backside dielectric layer 224a of the first DRAM structure 22a of the DRAM stacking 24 bonds to the third backside dielectric layer 138 of the logic structure 12 to form the dielectric to dielectric bond between the logic structure 12 and the DRAM stacking 24. In some embodiments, the backside dielectric layer 224a of the first DRAM structure 22a of the DRAM stacking 24 directly contacts the third backside dielectric layer 138 of the logic structure 12. The dielectric to dielectric bond may be formed through an fusion process, such as oxide fusion.

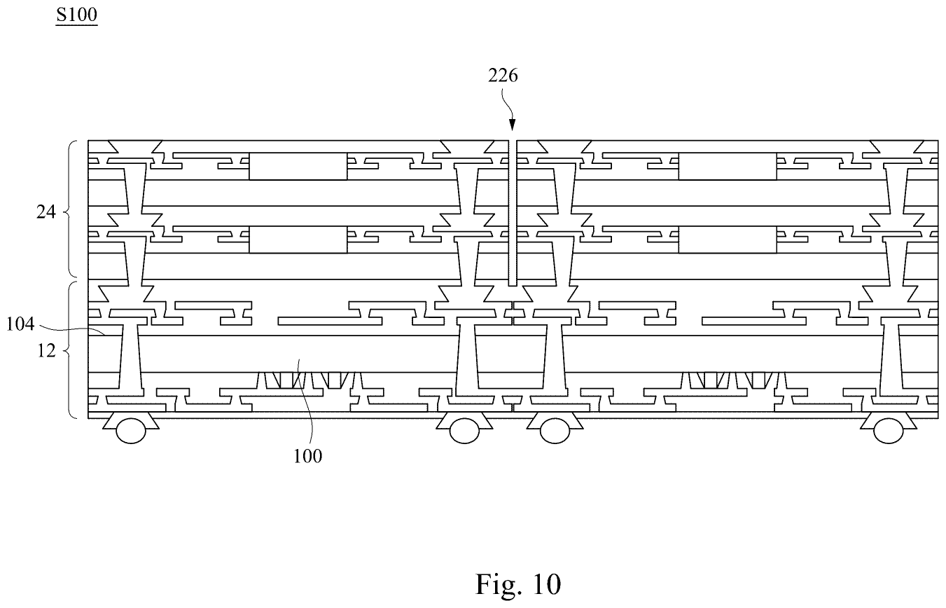

Referring to FIG. 10, the method goes to step S100. The plurality of the DRAM stackings 24 are stacked on the backside 104 of the thinned substrate 100 of the logic structure 12 in a method the same as the method described in FIG. 9. A trench 226 is formed between the adjacent DRAM stackings 24. In some embodiments, bonding the DRAM stackings 24 and the logic structure 12 together may use bumps and underfills. However, the bumps may limit the speed due to high resistance of the bumps, and the underfills may generate heat during chip operation. In the method described in the present disclosure, bonding the DRAM stackings 24 and the logic structure 12 together without bumps and underfills may improve the speed and heat dissipation.

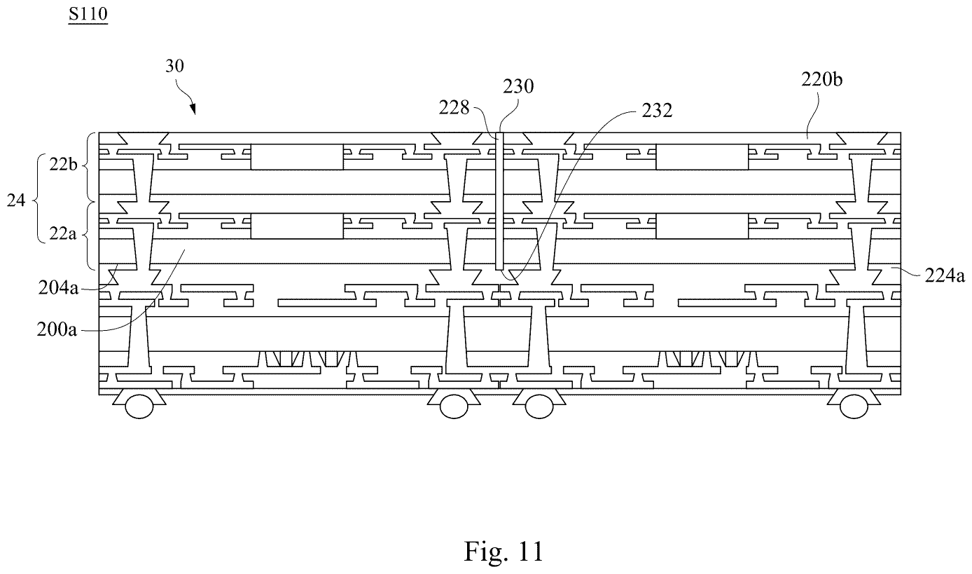

Referring to FIG. 11, the method goes to step S110. A semiconductor device 30 is formed. A molding layer 228 is formed in the trench 226 (as shown in FIG. 10) between the adjacent DRAM stackings 24. The molding layer 228 is formed by filling a molding material into the trench 226 (as shown in FIG. 10), then performing a reflow process to cure the molding material, followed by removing an excess portion of a cured molding material over a frontside surface of the second DRAM structure 22b of the DRAM stacking 24. The molding layer 228 includes a frontside 230 and a backside 232 opposite to the frontside 230. The frontside 230 of the molding layer 228 is adjacent the frontside surface of the third frontside dielectric layer 220b of the second DRAM structure 22b of the DRAM stacking 24. The backside 232 of the molding layer 228 is adjacent a backside surface of the backside dielectric layer 224a of the first DRAM structure 22a of the DRAM stacking 24. Further, a level of the backside 232 of the molding layer 228 is lower than a level of the backside 204a of the substrate 200a of the first DRAM structure 22a of the DRAM stacking 24.

In the present disclosure, the DRAM structure may form into the DRAM stackings first, stacked sequentially on the backside of the thinned substrate of the logic structure to increases an accumulated amount of DRAM structure in the semiconductor device, so that decreases the thickness of the semiconductor device. Further, the semiconductor device of the present disclosure improves the heat dissipation problem during operation.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming a semiconductor device, comprising:
forming a logic structure, wherein the logic structure includes a first substrate including a frontside and a backside opposite to the frontside, a first through silicon via (TSV) formed in the first substrate and penetrating through the frontside and the backside of the first substrate, a frontside redistribution layer (RDL) disposed on the frontside of the first substrate and connected to the first TSV, a bump disposed on the RDL and coupled to the first TSV through the frontside RDL, a backside RDL disposed on the backside of the first substrate and connected to the first TSV, a backside dielectric layer formed on the backside RDL, a backside metal pad disposed in the backside dielectric layer and coupled to the first TSV through the backside RDL, wherein a backside surface of the backside metal pad of the logic structure is coplanar with a backside surface of the backside dielectric layer of the logic structure;
forming a plurality of dynamic random access memory (DRAM) structures, wherein each of the plurality of DRAM structures includes a second substrate including a frontside and a backside opposite to the frontside, a second TSV penetrating through the frontside and the backside of the second substrate, a RDL disposed on the frontside of the second substrate and connected to the second TSV, a frontside dielectric layer disposed on the RDL, a metal pad disposed in the frontside dielectric layer and coupled to the second TSV through the RDL, a backside dielectric layer disposed on the backside of the second substrate, wherein a backside surface of the second TSV is coplanar with a backside surface of the backside dielectric layer of the DRAM structure;
vertically stacking the plurality of DRAM structures into at least one DRAM stacking;
disposing the at least one DRAM stacking on the backside of the first substrate of the logic structure, wherein the second TSV of most bottom DRAM structure of the DRAM stacking contacts the backside metal pad of the logic structure, and the backside dielectric layer of most bottom DRAM structure of the DRAM stacking contacts the backside dielectric layer of the logic structure; and
filling a molding layer around the DRAM stacking.

2. The method of claim 1, wherein a first through silicon via (TSV) formed in the first substrate and penetrating through the frontside and the backside of the first substrate comprises:
forming the first TSV in a substrate extending upwardly in a direction of the frontside of the first substrate;
removing a portion of the substrate in a direction of the backside of the first substrate to form the first substrate, exposing a backside portion of the first TSV;
depositing a dielectric material on the backside of the first substrate and overlying the backside portion of the first TSV; and
performing a planarizing process removing a portion of the dielectric material to form the backside dielectric layer of the logic structure, wherein a backside surface of the backside dielectric layer of the logic structure is coplanar with a backside surface of the first TSV.

3. The method of claim 1, wherein a second TSV penetrating through the frontside and the backside of the second substrate comprises:
forming the second TSV in a substrate extending upwardly in a direction of the frontside of the second substrate;
removing a portion of the substrate in a direction of the backside of the second substrate to form the second substrate, exposing a backside portion of the second TSV;
depositing a dielectric material on the backside of the second substrate and overlying the backside portion of the second TSV; and
performing a planarizing process removing a portion of the dielectric material to form the backside dielectric layer of the DRAM structure, wherein a backside surface of the backside dielectric layer of the DRAM structure is coplanar with a backside surface of the second TSV.

4. The method of claim 1, wherein a backside redistribution layer disposed on the backside of the first substrate and connected to the first TSV comprises:
forming a second backside dielectric layer;
forming backside traces in the second backside dielectric layer and disposing at different height level in a direction parallel to the first substrate; and
forming a backside via in the second backside dielectric layer and connected to adjacent backside traces at different height level, wherein one of the backside traces directly contact the first TSV.

5. The method of claim 4, wherein a backside metal pad disposed in the backside dielectric layer and coupled to the first TSV through the backside RDL comprises:
forming the backside metal pad on the backside RDL, wherein the backside metal pad directly contacts another one of the backside traces.

6. The method of claim 1, wherein disposing the at least one DRAM stacking on the backside of the first substrate of the logic structure comprising:
performing an anneal process to bond the second TSV of most bottom DRAM structure of the DRAM stacking and the backside metal pad of the logic structure.

7. The method of claim 1, wherein disposing the at least one DRAM stacking on the backside of the first substrate of the logic structure comprising:
performing an fusion process to bond the backside dielectric layer of most bottom DRAM structure of the DRAM stacking and the backside dielectric layer of the logic structure.

8. The method of claim 1, further comprising:
forming a plurality of DRAM stackings;
disposing the plurality of the DRAM stackings on the backside of the first substrate of the logic structure, wherein a trench is formed between the adjacent plurality of the DRAM stackings; and
filling the molding layer into the trench.

9. The method of claim 1, wherein vertically stacking the plurality of DRAM structures into the DRAM stacking comprises:
the second TSV of one of the plurality of DRAM structures directly contacts the metal pad of another one of the plurality of DRAM structures.

10. The method of claim 1, wherein the second TSV of most bottom DRAM structure of the DRAM stacking contacts the backside metal pad of the logic structure comprises electrically connecting the DRAM structure to the logic structure.

11. The method of claim 1, wherein vertically stacking the plurality of DRAM structures into at least one DRAM stacking further comprising:
stacking aligned a DRAM wafer on another DRAM wafer to form a stacked DRAM wafer, wherein the DRAM wafer includes a plurality of DRAM structure,
dicing the stacked DRAM wafer into a plurality of DRAM stackings.

12. The method of claim 1, wherein filling a molding layer around the DRAM stacking further comprising:
performing a reflow process to form the molding layer.

13. A semiconductor device, comprising:
a logic structure, wherein the logic structure comprises:
a first substrate including a frontside and a backside opposite to the frontside;
a first through silicon via (TSV) in the first substrate and penetrating through the frontside and the backside of the first substrate;
a frontside redistribution layer (RDL) on the frontside of the first substrate and connected to the first TSV,
a protecting layer on the frontside RDL;
a frontside metal pad on the frontside RDL through the protecting layer;
a bump on the frontside metal pad;
a backside RDL on the backside of the first substrate and connected to the first TSV;
a backside dielectric layer on the backside RDL; and
a backside metal pad in the backside dielectric layer and coupled to the first TSV through the backside RDL;
a DRAM stacking formed of one or more DRAM structure vertically stacked, wherein each of the one or more DRAM structure comprises:
a second substrate including a frontside and a backside opposite to the frontside;
a second TSV penetrating through the frontside and the backside of the second substrate;
a DRAM cell on the frontside of the second substrate;
a RDL on the frontside of the second substrate around the DRAM cell and connected to the second TSV;
a frontside dielectric layer on the RDL;
a metal pad in the frontside dielectric layer and coupled to the second TSV through the RDL;
a backside dielectric layer on the backside of the second substrate, wherein the DRAM stacking disposed on the backside of the first substrate of the logic structure, the second TSV of most bottom DRAM structure of the DRAM stacking contacts the backside metal pad of the logic structure, and the backside dielectric layer of most bottom DRAM structure of the DRAM stacking contacts the backside dielectric layer of the logic structure; and
a molding layer on the logic structure surrounding the DRAM stacking.

14. The semiconductor device of claim 13, wherein a backside surface of the backside metal pad is coplanar with a backside surface of the backside dielectric layer of the logic structure.

15. The semiconductor device of claim 13, wherein a backside surface of the molding layer is lower than a backside surface of the second substrate.

16. The semiconductor device of claim 13, wherein a frontside surface of the DRAM stacking is coplanar with a frontside surface of the molding layer.

17. The semiconductor device of claim 13, further comprising:
a plurality of DRAM stackings on the backside of the first substrate of the logic structure.

18. The semiconductor device of claim 17, further comprising:
a trench between the adjacent plurality of DRAM stackings; and
a molding layer in the trench.

19. The semiconductor device of claim 13, wherein the second TSV of most bottom DRAM structure of the DRAM stacking directly contacts the backside metal pad of the logic structure.

20. The semiconductor device of claim 13, wherein the backside dielectric layer of the most bottom DRAM structure of the DRAM stacking directly contacts the backside dielectric layer of the logic structure.
